(19) United States
(12) Patent Application Publication
(10) Pub. No.: US 2019/0285682 A1
(43) Pub. Date: Sep. 19, 2019

(54) FAILURE DETECTING DEVICE AND METHOD FOR FAILURE TESTING ELECTRONIC DEVICE

(71) Applicants: Fu Tai Hua Industry (Shenzhen) Co., Ltd., Shenzhen (CN); HON HAI PRECISION INDUSTRY CO., LTD., New Taipei (TW)

(72) Inventor: CHENG-XIANG LIU, Shenzhen (CN)

(21) Appl. No.: 15/980,825

(22) Filed: May 16, 2018

(30) Foreign Application Priority Data
Mar. 14, 2018 (CN) 201810208360.9

(51) Int. Cl. G01R 31/00

(52) U.S. Cl. CPC G01R 31/003

(57) ABSTRACT

A failure testing device implemented on an electronic device includes a detecting device and a processor. The detecting device detects environmental parameters of the electronic device. The processor controls the detecting device to detect the environmental parameters of the electronic device, obtains the environmental parameters detected by the detecting device, determines whether the obtained environmental parameters exceed a preset range, tests components and running conditions of the electronic device, and compares the test data and the environmental parameters to data from a database to determine a reason for failure of the electronic device. The database stores values of the environmental parameters which would cause the electronic device to fail, test data when the electronic device has failed, and causes of failure.

### FIELD

The subject matter herein generally relates to testing of electronic devices, and more particularly to a failure detecting device and method for failure testing an electronic device.

### BACKGROUND

Generally, when an electronic device loses functionality or is damaged, the electronic device must be taken apart, and each component of the electronic device must be inspected to determine a cause of failure of the electronic device.

### BRIEF DESCRIPTION OF THE DRAWINGS

Implementations of the present disclosure will now be described, by way of example only, with reference to the attached figures.

FIG. 1 is a block diagram of a failure detecting device in communication with an electronic device and a test server.

FIG. 2 is a block diagram of the failure detecting device of FIG. 1.

FIG. 3 is a block diagram of a detecting device of the failure detecting device of FIG. 2.

FIG. 4 is a block diagram of the test server of FIG. 1.

FIG. 5 is a block diagram of a testing system implemented in the failure detecting device.

FIG. 6 is a flow chart of a method for failure testing an electronic device.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “comprising” means “including, but not necessarily limited to”; it specifically indicates open-ended inclusion or membership in a so-described combination, group, series and the like.

In general, the word “module” as used hereinafter refers to logic embodied in hardware or firmware, or to a collection of software instructions, written in a programming language such as, for example, Java, C, or assembly. One or more software instructions in the modules may be embedded in firmware such as in an erasable-programmable read-only memory (EPROM). It will be appreciated that the modules may comprise connected logic units, such as gates and flip-flops, and may comprise programmable units, such as programmable gate arrays or processors. The modules described herein may be implemented as either software and/or hardware modules and may be stored in any type of computer-readable medium or other computer memory device.

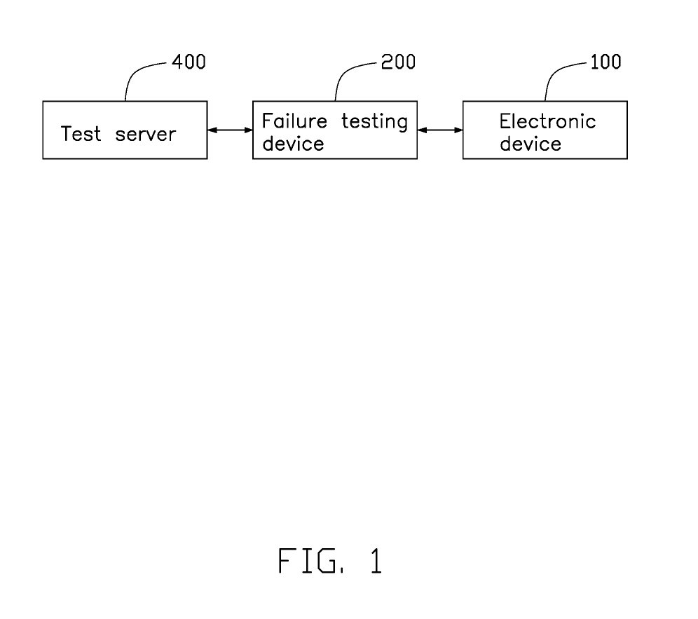

FIG. 1 illustrates an embodiment of a failure testing device 200 implemented on an electronic device 100. The failure testing device 200 tests a reason of failure of the electronic device 100. The failure testing device 200 is in communication with a test server 400 to exchange a plurality of data. In at least one embodiment, the electronic device 100 may be, but is not limited to, a smart phone, a tablet computer, a personal digital assistant, a smart watch, a smart bracelet, or other portable electronic devices. The failure testing device 200 may be located on a protective cover of the electronic device 100. The failure testing device 200 may also be directly installed in or on the electronic device 100, such as on a housing of the electronic device 100.

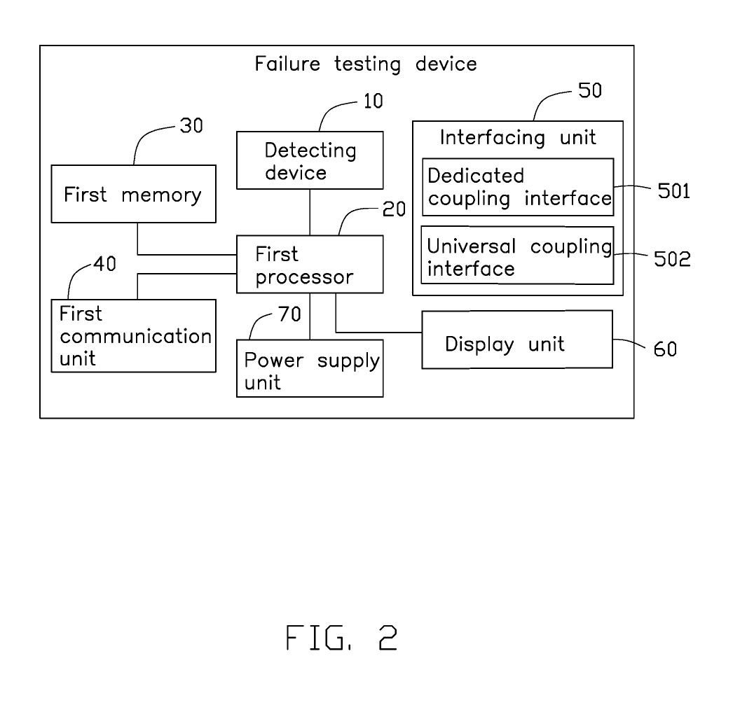

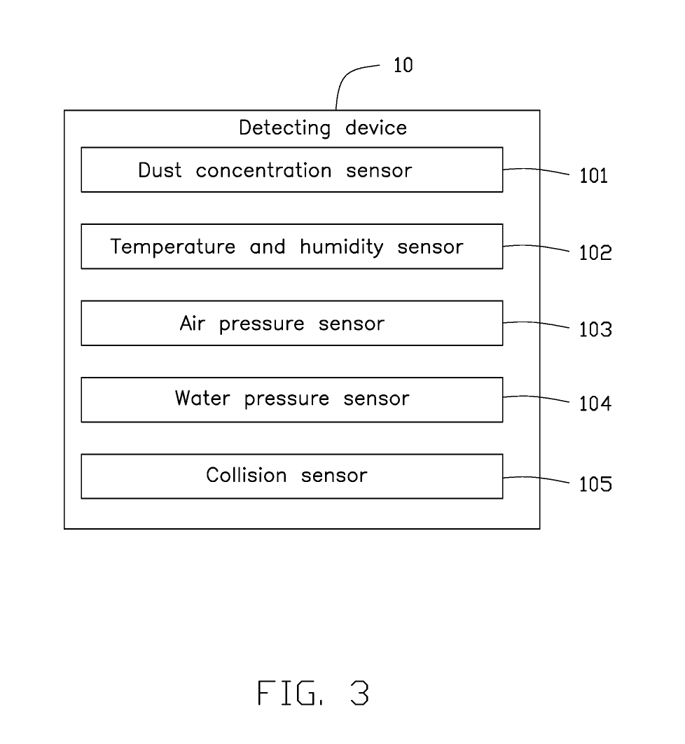

Referring to FIG. 2 and FIG. 3, in at least one embodiment, the failure testing device 200 includes a detecting device 10, a first processor 20, a first memory 30, a first communication unit 40, an interfacing unit 50, a display unit 60, and a power supply unit 70.

The detecting device 10 detects environmental parameters of the electronic device 100. In at least one embodiment, the environmental parameters detected by the detecting device 10 include, but are not limited to, a dust concentration value, a temperature and humidity value, an air pressure value, a water pressure value, and an impact force value. In at least one embodiment, the detecting device 10 includes a dust concentration sensor 101, a temperature and humidity sensor 102, an air pressure sensor 103, a water pressure sensor 104, and a collision sensor 105. The dust concentration sensor 101 detects the dust concentration value of an environment of the electronic device 100. The temperature and humidity sensor 102 detects the temperature and humidity value of the environment of the electronic device 100. The air pressure sensor 103 detects the air pressure value of the environment of the electronic device 100. The air pressure value represents an altitude of the environment of the electronic device 100. The water pressure sensor 104 senses the water pressure when the electronic device 100 is in a water environment. The collision sensor 105 senses the impact force when the electronic device 100 is impacted.

The first processor 20 may be a central processing unit, a microprocessing unit, a data processing chip, or other suitable processing chip.

The first memory 30 stores a plurality of data of the failure testing device 200. In at least one embodiment, the first memory 30 may include, but is not limited to, a read-only memory, a random access memory, a programmable read-only memory, an erasable programmable read-only memory, a one-time programmable read-only memory, an electrically-erasable programmable read-only memory, an electrically-erasable programmable read-only memory, a compact disc read-only memory, or other optical memory disk, magnetic memory disc, or magnetic memory tape.

The first communication unit 40 establishes communication with the test server 400. In at least one embodiment, the first communication unit 40 establishes communication with the test server 400 through a wireless network. The wireless network may be, but is not limited to, WIFI, BLUETOOTH, a cellular network, a satellite network, or the like.

The interfacing unit 50 includes a dedicated coupling interface 501 and a universal coupling interface 502. The dedicated coupling interface 501 provides a wired connection to the electronic device 100. In at least one embodiment, the dedicated coupling interface 501 may be a universal serial bus (USB) port, which the failure testing device 200 may couple to with a USB cable. The universal coupling interface 502 is configured to couple to another electronic device, such as another mobile phone or computer, or to a charger. The universal coupling interface 502 providing a coupling means to another electronic device not only couples the failure testing device 200 to another electronic device, but also provides a means for coupling the electronic device 100 to another electronic device. For example, the electronic device 100 can send data to the failure testing device 200 through the dedicated coupling interface 501, and then the failure testing device 200 can send the data to another electronic device through the universal coupling interface 502. Furthermore, when the failure testing device 200 is coupled to a charger through the universal coupling interface 502, the charger can not only charge the failure testing device 200, the charger can also charge the electronic device 100.

The display unit 60 displays a testing process and a testing result. In at least one embodiment, the display unit 60 may be, but is not limited to, a touch screen, a liquid crystal display, or the like. In another embodiment, the display unit 60 may be a touch screen of the electronic device 100.

The power supply unit 70 provides power to the failure testing device 200. In at least one embodiment, the power supply unit 70 includes a power management chip (not shown in figures) and a battery (not shown in figures).

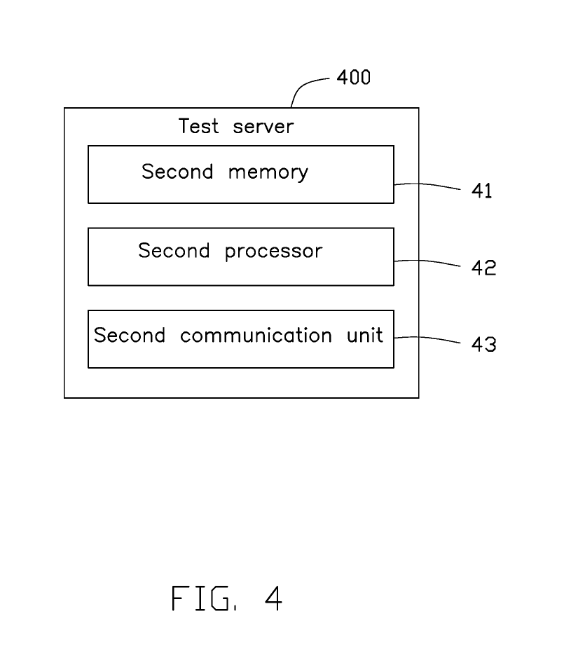

Referring to FIG. 4, the test server 400 includes a second memory 41, a second processor 42, and a second communication unit 43.

The second memory 41 stores a plurality of data of the test server 400, such as a database and a plurality of software instructions. In at least one embodiment, the second memory 41 may include, but is not limited to, a read-only memory, a random access memory, a programmable read-only memory, an erasable programmable read-only memory, a one-time programmable read-only memory, an electrically-erasable programmable read-only memory, an electrically-erasable programmable read-only memory, a compact disc read-only memory, or other optical memory disk, magnetic memory disc, or magnetic memory tape.

In at least one embodiment, the second memory 41 stores a database. The database stores values of the environmental parameters which would cause the electronic device to fail, test data when the electronic device has failed, and causes of failure. The environmental parameters include a dust concentration value, a temperature and humidity value, an air pressure value, a water pressure value, and an impact force value. The test data includes the environmental parameter values when the electronic device 100 has failed, such as the temperature of the electronic device 100, a speed of a central processing unit, and a battery power level, for example. The reason for failure may include a circuit board short circuiting, the battery losing power, or the electronic device powering off, for example.

The database includes a dust failure database, a waterproof failure database, a temperature and humidity failure database, and a collision failure database prestored in the second memory 41. The dust failure database includes a dust concentration value causing failure of the electronic device 100 and a failed component of the electronic device 100. The waterproof failure database includes a water pressure value and/or a water depth value causing failure of the electronic device 100 and a failed component of the electronic device 100. The temperature and humidity failure database includes a temperature value and a humidity value causing failure of the electronic device 100 and a failed component of the electronic device 100. Using a mobile phone as an example of the electronic device 100, a battery of the mobile phone is operable within a predetermine temperature range, such as −20 degrees Celsius to 60 degrees Celsius. When the temperature exceeds the predetermined temperature range, the battery will be affected and cause the mobile phone to power off. Thus, the temperature and humidity database may include, but is not limited to, the range of temperature causing failure of the mobile phone and the battery as the failed component.

The second processor 42 may be a central processing unit, a microprocessing unit, a data processing chip, or other suitable processing chip.

The second communication unit 43 establishes communication with at least one failure testing device 200. In at least one embodiment, the second communication unit 43 establishes communication with the failure testing device 200 through a wireless network. The wireless network may be, but is not limited to, WIFI, BLUETOOTH, a cellular network, a satellite network, or the like.

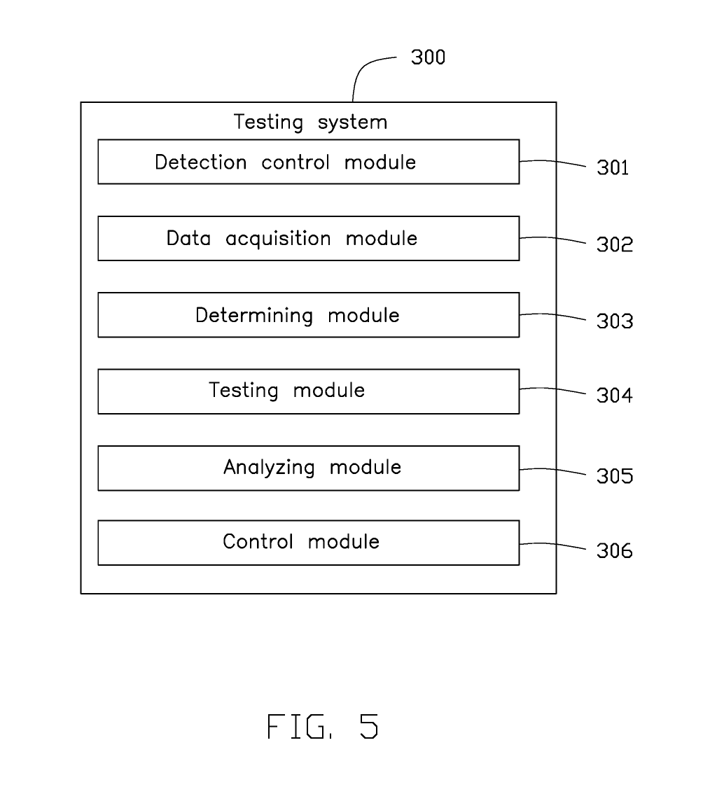

FIG. 5 illustrates an embodiment of a testing system 300. The testing system 300 includes a plurality of modules, which include one or more software programs in the form of computerized codes stored in the first memory 30. The computerized codes include instructions executed by the first processor 20 to provide functions for the testing system 300. The testing system 300 includes a detection control module 301, a data acquisition module 302, a determining module 303, a testing module 304, an analyzing module 305, and a control module 306.

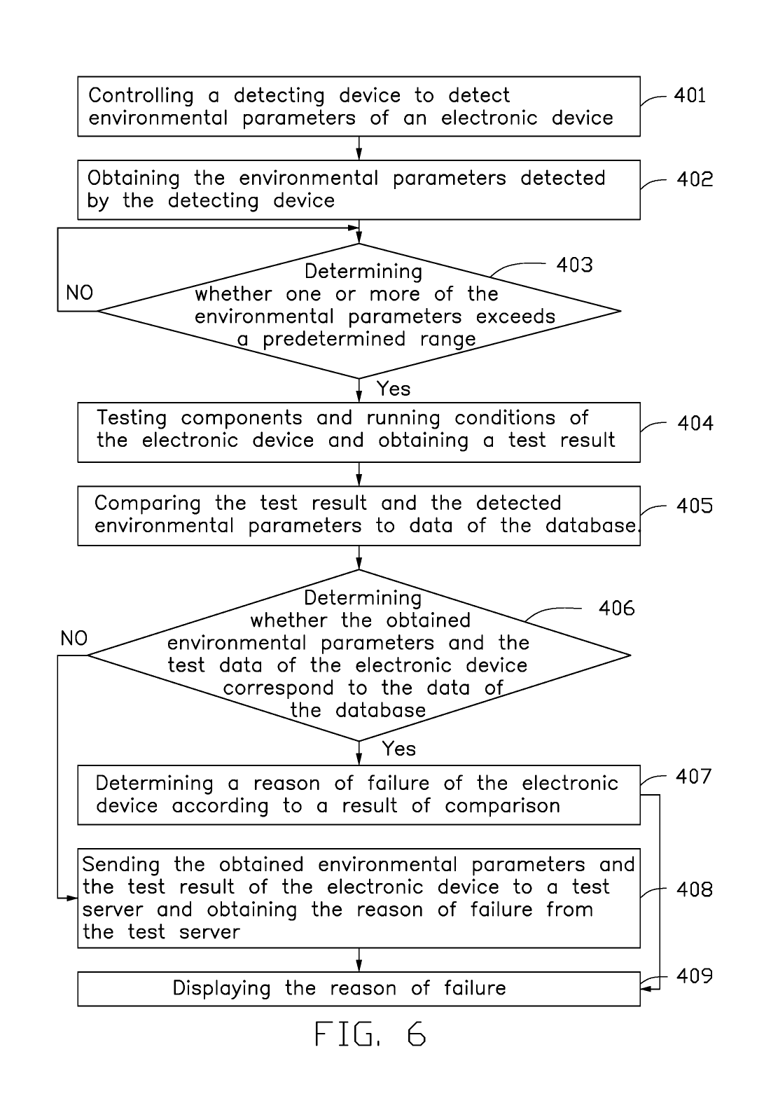

FIG. 6 illustrates a flowchart of an exemplary method for failure testing an electronic device. The example method is provided by way of example, as there are a variety of ways to carry out the method. The method described below can be carried out using the configurations illustrated in FIGS. 1-5, for example, and various elements of these figures are referenced in explaining the example method. Each block shown in FIG. 6 represents one or more processes, methods, or subroutines carried out in the example method. Furthermore, the illustrated order of blocks is by example only, and the order of the blocks can be changed. Additional blocks can be added or fewer blocks can be utilized, without departing from this disclosure. The example method can begin at block S401.

At block S401, the detecting module 301 controls the detecting device 10 to detect the environmental parameters of the electronic device 100.

At block S402, the data acquisition module 302 obtains the environmental parameters detected by the detecting device 10.

At block S403, the determining module 303 determines whether one or more of the environmental parameters exceeds the predetermined range. If one or more of the environmental parameters exceeds the predetermined range, block S404 is implemented. If one or more of the environmental parameters does not exceed the predetermined range, block S403 is repeated.

In at least one embodiment, the first memory 30 stores a predetermined range of each of the environmental parameters. The determining module 303 compares the obtained environmental parameters to the predetermined ranges, and determines whether one or more environmental parameters exceeds the predetermined range according to a result of comparison.

At block S404, the testing module 304 tests components and running conditions of the electronic device 100 and obtains a test result. In another embodiment, the testing module 304 tests the electronic device 100 in response to a command from the test server 400.

At block S405, the analyzing module 305 compares test data and the detected environmental parameters to data of the database. In at least one embodiment, the analyzing module 305 obtains the database from the test server 400 and stores the database in the first memory 20. In another embodiment, the analyzing module 305 sends the detected environmental parameters and the test data to the test server 400, and the test server 400 compares the detected environmental parameters and the test data to the database stored in the second memory 41.

At block S406, the analyzing module 305 determines whether the obtained environmental parameters and the test data of the electronic device 100 correspond to the data of the database. When the obtained environmental parameters and the test data of the electronic device 100 correspond to the data of the database, block S407 is implemented. When the obtained environmental parameters and the test data of the electronic device 100 do not correspond to the data of the database, block S408 is implemented.

At block S407, the analyzing module 305 determines a reason of failure of the electronic device 100 according to the result of comparison.

At block S408, the analyzing module 305 sends, through the first communication unit 40, the obtained environmental parameters and the test data of the electronic device 100 to the test server 400 and obtains, from the test server 400, the reason of failure. In at least one embodiment, the reason of failure is determined by a professional analyzer who has analyzed the environmental parameters and the test data. Furthermore, the test server 400 updates the database according to the environmental parameters, the test data, and the reason of failure provided by the professional analyzer. In another embodiment, the reason of failure is determined according to an external analysis device or a cloud server in communication with the test server 400, for example.

At block 409, the control module 306 displays the reason of failure on the display unit 60.

In at least one embodiment, the electronic device 100 and the testing system 300 each includes a unique identification code. Before block S401, the test server 400 may download the testing system 300 and link the unique identification code of the electronic device 100 to the unique identification code of the testing system 300. Different electronic devices 100 may require different testing systems 300. Thus, a user may download the correct testing system 300 according to the unique identification code of the electronic device 100.

In another embodiment, the testing system 300 may be preinstalled in the failure testing device 200, so that when a user uses the failure testing device 200, the testing system 300 is simultaneously obtained. For example, when the failure testing device 200 is installed on a protective cover of the electronic device 100, the user may use the testing system 300.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A failure testing device implemented on an electronic device, the failure testing device comprising:
a detecting device configured to detect environmental parameters of the electronic device;
a processor; and
a memory configured to store a plurality of instructions, which when executed by the processor, cause the processor to:
control the detecting device to detect the environmental parameters of the electronic device;
obtain the environmental parameters detected by the detecting device;
determine whether the obtained environmental parameters exceed a preset range;
test components and running conditions of the electronic device, when it is determined that the environmental parameters exceed the preset range, and obtain test data of the electronic device; and
compare the test data and the environmental parameters to data from a database to determine a reason for failure of the electronic device;
wherein the database stores values of the environmental parameters which would cause the electronic device to fail, test data when the electronic device has failed, and causes of failure.

2. The failure testing device of claim 1, wherein the database comprises a dust failure database, a waterproof failure database, a temperature and humidity database, and a collision failure database.

3. The failure testing device of claim 2, wherein the detecting device comprises a dust concentration sensor, a temperature and humidity sensor, an air pressure sensor, a water pressure sensor, and a collision sensor; the environmental parameters comprise a dust concentration value, a temperature and humidity value, an air pressure value, a water pressure value, and an impact force value.

4. The failure testing device of claim 1, wherein the detecting device is located on a protective cover of the electronic device.

5. The failure testing device of claim 1, wherein the detecting device further comprises a first communication unit configured to establish communication with a test server and obtain the database from the test server.

6. The failure testing device of claim 5, wherein when the obtained environmental parameters and the test data of the electronic device do not correspond to data of the database, the processor sends the obtained environmental parameters and the test data through the first communication unit to the test server, and obtains corresponding data from the test server to analyze to determine the reason for failure.

7. The failure testing device of claim 1, wherein the detecting device further comprises an interfacing unit comprising a dedicated coupling interface and a universal coupling interface; the dedicated coupling interface provides a wired connection to the electronic device; the universal coupling interface is configured to couple to another electronic device or to a charger.

8. A failure testing method implemented on a failure testing device comprising a detecting device, the method comprising:
controlling the detecting device to detect the environmental parameters of the electronic device;
obtaining the environmental parameters detected by the detecting device;
determining whether the obtained environmental parameters exceed a preset range;
testing components and running conditions of the electronic device, when it is determined that the environmental parameters exceed the preset range, and obtain test data of the electronic device; and
comparing the test data and the environmental parameters to data from a database to determine a reason for failure of the electronic device;
wherein the database stores values of the environmental parameters which would cause the electronic device to fail, test data when the electronic device has failed, and causes of failure.

9. The failure testing method of claim 8, wherein when the obtained environmental parameters and the test data of the electronic device do not correspond to data of the database, the processor sends the obtained environmental parameters and the test data through the first communication unit to the test server, and obtains corresponding data from the test server to analyze to determine the reason for failure.

10. The failure testing method of claim 8, wherein the database comprises a dust failure database, a waterproof failure database, a temperature and humidity database, and a collision failure database; the environmental parameters comprise a dust concentration value, a temperature and humidity value, an air pressure value, a water pressure value, and an impact force value.
